(19) United States
(12) Patent Application Publication
(10) Pub. No.: US 2017/0271224 A1
(43) Pub. Date: Sep. 21, 2017

(54) SEMICONDUCTOR DEVICE

(71) Applicant: FUJI ELECTRIC CO., LTD., Kawasaki-shi (JP)

(72) Inventor: Yuichiro HINATA, Matsumoto-city (JP)

(73) Assignee: FUJI ELECTRIC CO., LTD., Kawasaki-shi (JP)

(21) Appl. No.: 15/452,118

(22) Filed: Mar. 7, 2017

(30) Foreign Application Priority Data
Mar. 18, 2016 (JP) 2016-054849

(51) Int. Cl. H01L 23/16; H01L 23/053; H01L 25/11

(52) U.S. Cl. CPC H01L 23/16; H01L 25/115; H01L 23/053

(57) ABSTRACT

A semiconductor device, including a plurality of semiconductor units disposed in a matrix, and a capsule encapsulating the plurality of semiconductor units. Each semiconductor unit includes a semiconductor element and another capsule encapsulating the semiconductor element. Each semiconductor unit further has a plurality of convex portions formed on a front surface thereof, and an engagement portion through which the semiconductor unit engages with at least one of the other semiconductor units.

### CROSS-REFERENCE TO RELATED APPLICATION

This application is based upon and claims the benefit of priority of the prior Japanese Patent Application No. 2016-054849, filed on Mar. 18, 2016, the entire contents of which are incorporated herein by reference.

### BACKGROUND OF THE INVENTION

1. Field of the Invention

The embodiments discussed herein relate to a semiconductor device.

2. Background of the Related Art

Power semiconductor modules include semiconductor elements such as IGBT (Insulated Gate Bipolar Transistors), power MOSFETs (Metal Oxide Semiconductor Field Effect Transistors) and FWD (Free Wheeling Diodes), and are in widespread use as power converting apparatuses and in other applications.

As one example, a power semiconductor module includes semiconductor elements and a laminated substrate. The laminated substrate has an insulating substrate with a circuit board formed on its front surface and a metal plate formed on its rear surface, and has semiconductor elements mounted via solder on the circuit board. This power semiconductor module also includes a printed circuit board that is disposed facing the laminated substrate and is formed with conductive posts that are joined and electrically connected to both the semiconductor elements and the circuit board. The semiconductor elements, laminated substrate, and printed circuit board are also encapsulated in a first capsule composed of sealing resin (see, for example, Japanese Laid-open Patent Publication No. 2009-064852).

As one example, a semiconductor device is configured by disposing four of these power semiconductor modules (or “semiconductor units”) in a two-row, two-column arrangement, providing a connection unit between the control electrodes and the main terminals of the respective semiconductor units, and encapsulating all of the semiconductor units and the connection unit in a second capsule composed of sealing resin. By constructing a semiconductor device including four semiconductor units, it is possible to increase the ampacity.

The first capsule that constructs a semiconductor unit has a release agent or the like applied to it to improve the release properties from the mold used during the sealing process. This lowers the adhesion between the first capsules and the second capsule which constructs the semiconductor device by encapsulating the semiconductor units, resulting in the risk of separation between the first capsules and the second capsule. If the capsules gradually become separated within a semiconductor device and the semiconductor units are no longer completely encapsulated, there is the risk of the semiconductor units shifting and of mechanical damage and breakage of the semiconductor device.

### SUMMARY OF THE INVENTION

In one aspect of the embodiments, there is provided a semiconductor device including: a plurality of semiconductor units which each include a semiconductor element and a first capsule that is formed so as to encapsulate the semiconductor element and has a plurality of convex portions formed on a front surface thereof, which are disposed in a matrix, which are equipped with engagement portions that engage one another, and which are connected by the engagement portions; and a second capsule formed so as to encapsulate the semiconductor units.

The advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view of a semiconductor device according to a first embodiment;

FIG. 2 is a cross-sectional view of the semiconductor device according to the first embodiment;

FIG. 3 is a plan view of a semiconductor unit according to the first embodiment;

FIG. 4 is a cross-sectional view of a semiconductor unit according to the first embodiment.

FIG. 5 is a plan view of a semiconductor unit according to a second embodiment; and

FIG. 6 is a cross-sectional view of a semiconductor unit according to a third embodiment.

### DETAILED DESCRIPTION OF THE INVENTION

### First Embodiment

A first embodiment will now be described with reference to the attached drawings.

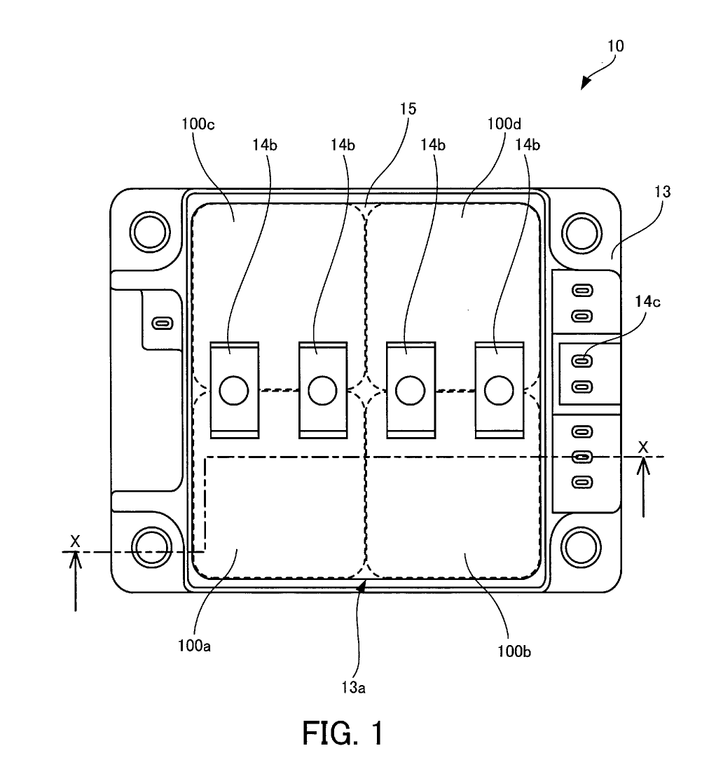

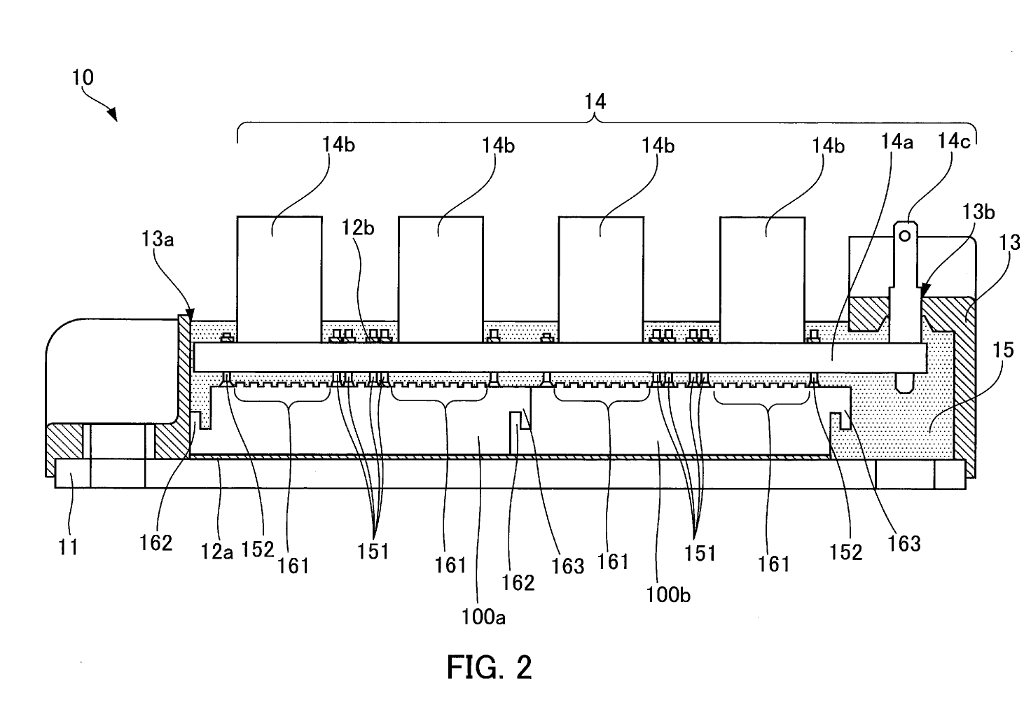

First, a semiconductor device will be described with reference to FIGS. 1 and 2.

FIG. 1 is a plan view of a semiconductor device according to the first embodiment.

Note that in FIG. 1, the disposed positions of semiconductor units 100a, 100b, 100c, and 100d are indicated by broken lines.

FIG. 2 is a cross-sectional view of a semiconductor device according to the first embodiment.

Note that FIG. 2 is a cross-sectional view taken along the dot-dash line X-X in FIG. 1.

The semiconductor device 10 includes the plurality of semiconductor units 100a, 100b, 100c, and 100d (collectively referred to in this specification as the “semiconductor units 100”), a baseplate 11, and a connection unit 14. Note that the semiconductor units 100 will be described in detail later. The rear surfaces of the respective semiconductor units 100 are joined to the baseplate 11 by solder 12a. Control terminals 152 and main terminals 151 (hereinafter collectively referred to as the “connection terminals”) of the plurality of semiconductor units 100 are joined to the connection unit 14 by solder 12b. The connection unit 14 electrically connects the plurality of semiconductor units 100 in parallel. Note that in the present embodiment, an example where the semiconductor device 10 is configured with four semiconductor units 100 in a two by two (two rows and two columns) arrangement is described.

The baseplate 11 is composed of a metal with favorable thermal conductivity, such as copper or aluminum.

The connection unit 14 includes a printed circuit board 14a, external connection terminals 14b, and external control terminals 14c.

The printed circuit board 14a is configured by stacking a plurality of circuit layers (not illustrated) and insulating layers (also not illustrated).

The external connection terminals 14b are electrically connected to the circuit layers included in the printed circuit board 14a. The external connection terminals 14b are connected to an external device and output therethrough output currents of the semiconductor units 100.

The external control terminals 14c are electrically connected to a corresponding circuit layer of the printed circuit board 14a. The external control terminals 14c are connected to an external device that outputs control signals and is used to input predetermined control signals.

Note that the external connection terminals 14b are each electrically connected via a corresponding circuit layer of the printed circuit board 14a to the main terminals 151 of the semiconductor units 100. The external control terminals 14c are also electrically connected via a corresponding circuit layer of the printed circuit board 14a to the control terminals 152 of the semiconductor units 100.

A case 13 surrounds the outer circumference of the construction but exposes a rear surface of the baseplate 11. The plurality of semiconductor units 100 are disposed via the solder 12a on the baseplate 11 via an opening 13a in the case 13. The external control terminals 14c protrude from openings 13b in the case 13.

A second capsule 15 is produced by filling the inside of the case 13 with sealing resin so that the baseplate 11, the semiconductor units 100, and the connection unit 14 are encapsulated by the second capsule 15. Note that as one example, the second capsule 15 is constructed by hardening a sealing resin such as epoxy resin. Note also that the baseplate 11 and the case 13 may be omitted.

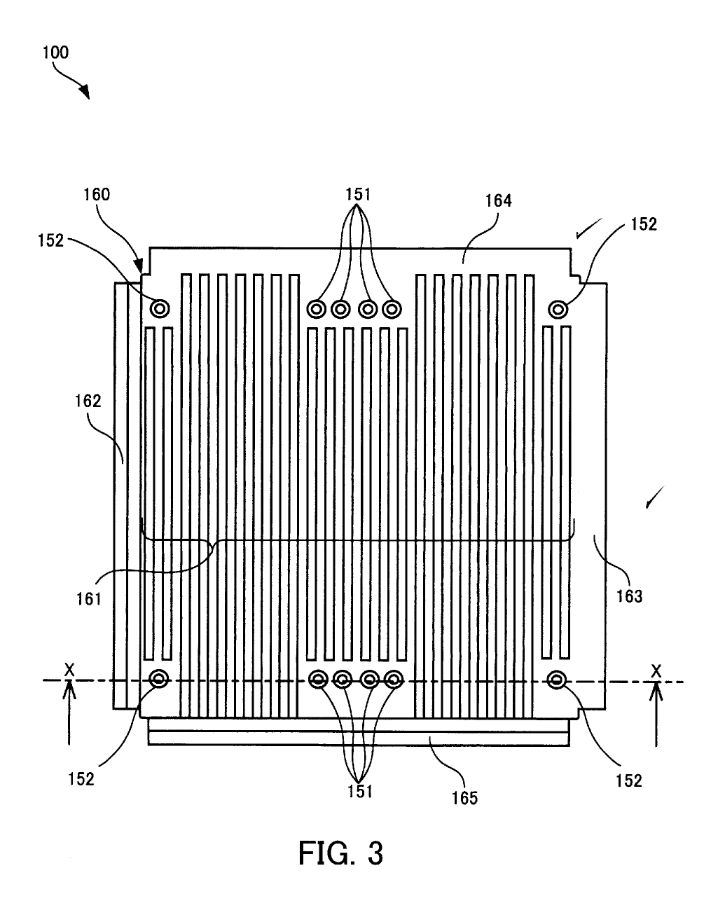

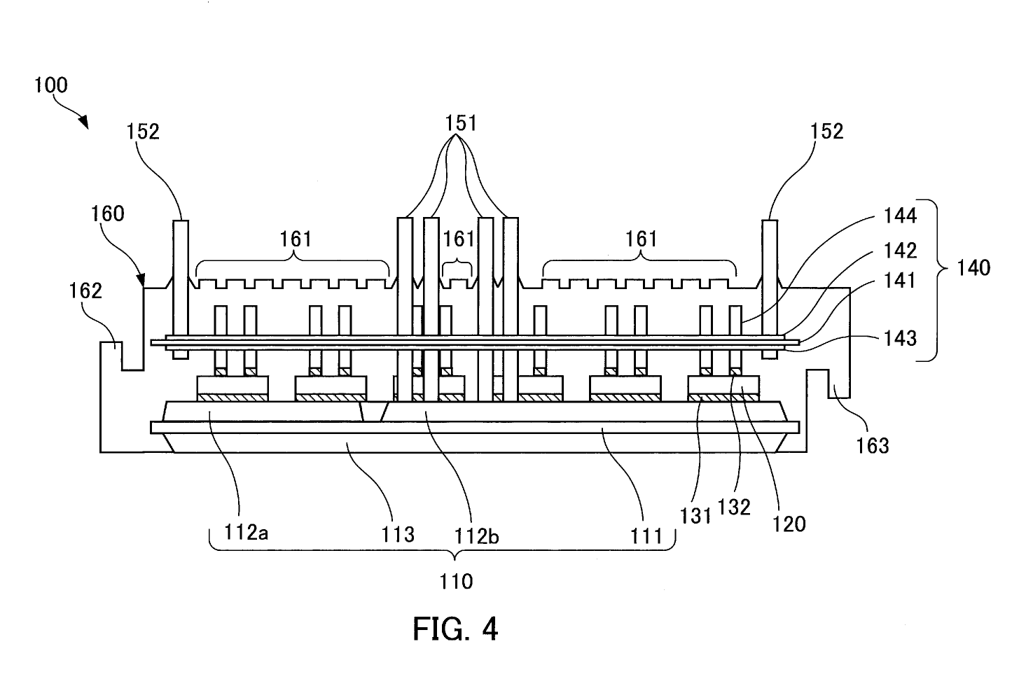

Next, the semiconductor units 100 will be described with reference to FIGS. 3 and 4.

FIG. 3 is a plan view of a semiconductor unit according to the first embodiment.

FIG. 4 is a cross-sectional view of a semiconductor unit according to the first embodiment.

Note that FIG. 4 is a cross-sectional view along the dot-dash line X-X in FIG. 3.

Each semiconductor unit 100 includes a laminated substrate 110, semiconductor elements 120, a printed circuit board 140, the main terminals 151, and the control terminals 152, and is configured by encapsulating these components in a first capsule 160.

The laminated substrate 110 is configured by stacking circuit boards 112a and 112b, an insulating board 111, and a metal plate 113. The circuit boards 112a and 112b are disposed on a front surface of the insulating board 111 and have patterns that construct predetermined circuits inside the semiconductor unit 100. The metal plate 113 is disposed on a rear surface of the insulating board 111. As examples, the insulating board 111 is made of aluminum nitride or silicon nitride, an insulating ceramic such as aluminum oxide, or a resin insulating material such as epoxy resin. The circuit boards 112a and 112b and the metal plate 113 are made of copper or aluminum, for example. As examples, the laminated substrate 110 can use a DCB (Direct Copper Bonded) substrate or an AMB (Active Metal Brazed) substrate.

As examples, IGBT, MOSFET, and FWD are used as appropriate as the semiconductor elements 120. The electrodes on the rear surfaces of the respective semiconductor elements 120 are joined to the circuit board 112b of the laminated substrate 110 using a joining material 131 such as solder.

The printed circuit board 140 includes a resin layer 141 and circuit layers 142 and 143 disposed on the front surface and the rear surface of the resin layer 141. The printed circuit board 140 is also equipped with a plurality of conductive posts 144 that protrude out on both front and rear surface sides of the printed circuit board 140. These conductive posts 144 are electrically connected to the circuit layers 142 and 143. The conductive posts 144 are electrically connected and attached to front surface electrodes (as examples, gate electrodes, emitter electrodes, or source electrodes) of the semiconductor elements 120 by a joining material 132 of a similar composition to the joining material 131.

The plurality of main terminals 151 pass through through-holes (not illustrated) of the printed circuit board 140 and are electrically connected to the circuit boards 112a and 112b of the laminated substrate 110. In a state where the main terminals 151 are respectively connected to external positive and negative electrodes, the semiconductor elements 120 produce an output in keeping with an inputted control signal.

The plurality of control terminals 152 are fixed to the printed circuit board 140 and are electrically connected to the circuit layers 142 and 143 of the printed circuit board 140. The control terminals 152 input control signals from outside and output the inputted control signals via the circuit layers 142 and 143 and the conductive posts 144 to the semiconductor elements 120.

As one example, the first capsule 160 is constructed by hardening a sealing resin such as epoxy resin. The first capsule 160 encapsulates the laminated substrate 110, the plurality of semiconductor elements 120, and the printed circuit board 140, with the main terminals 151 and the control terminals 152 connected to the printed circuit board 140 protruding from the first capsule 160. The first capsule 160 may also have convex portions constructed by forming channel portions 161 in a front surface of the first capsule 160. As depicted in FIG. 3, the channel portions 161 are formed in a single direction that is the up-down direction in FIG. 3. Engagement portions 162, 163, 164, and 165 are formed on the respective edges of the first capsule 160. The engagement portions 162 and 165 are formed in the shape of upward-facing keys and the engagement portions 163 and 164 are formed as in the shape of downward-facing keys.

Note that shapes corresponding to the channel portions 161 and the engagement portions 162 and 163 are formed in advance in the mold used to form the first capsule 160. A release agent is applied in advance to the inside of the mold, and then the laminated substrate 110, the semiconductor elements 120 that are provided via the joining material 131 on the circuit boards 112a and 112b of the laminated substrate 110, and the printed circuit board 140 equipped with the conductive posts 144 provided via the joining material 132 on the semiconductor elements 120 are placed inside the mold. After the inside of the mold housing the components has been filled with sealing resin, such as epoxy resin, and the sealing resin has hardened, the mold is removed. By doing so, a semiconductor unit 100 where the laminated substrate 110, the semiconductor elements 120, the printed circuit board 140, the main terminals 151, and the control terminals 152 are encapsulated by the first capsule 160 is obtained.

It is also possible to mount components, such as electronic components, so as to fit into the channel portions 161 on the front surface of the first capsule 160 of a semiconductor unit 100.

As depicted in FIG. 2, a plurality of the semiconductor units 100 are disposed via the solder 12a on the baseplate 11 in a connected state where the engagement portions 162 and 163 engage one another. The semiconductor units 100 in this state are housed in the case 13 and encapsulated in the second capsule 15.

For the plurality of semiconductor units 100 encapsulated in the second capsule 15, adhesion is improved by an anchoring effect produced by the channel portions 161 on the respective front surfaces of the semiconductor units 100 and engagement portions, out of the engagement portions 162, 163, 164, and 165, on sides where there is no engagement with another semiconductor unit 100. That is, the adhesion of the second capsule 15 to the semiconductor units 100 is improved.

If the semiconductor units 100 were not equipped with the engagement portions 162, 163, 164, and 165, parts of the second capsule 15 would be interposed between the semiconductor units 100 disposed in two rows and two columns. If an interposed part of the second capsule 15 between the semiconductor units 100 were to become separated from the semiconductor units 100, there would be the risk of the positions of the semiconductor units 100 shifting and of damage, breakage, and the like occurring at the separation locations. On the other hand, since the plurality of semiconductor units 100 according to the first embodiment are connected by engagement between the engagement portions 162 and 163, the second capsule 15 does not become interposed between the semiconductor units 100 and it is possible to suppress separation (peeling), which makes it possible to prevent the semiconductor units 100 from shifting.

The semiconductor device 10 described above includes a plurality of the semiconductor units 100 that are formed by encapsulating the semiconductor elements 120, are each equipped with a first capsule 160 that has the channel portions 161 that construct a plurality of convex portions formed on the front surface, are disposed in parallel, are further equipped with the engagement portions 162 and 163 that engage one another, and are connected by engagement portions, out of the engagement portions 162, 163, 164, and 165, that are decided by the layout of the semiconductor units 100. The semiconductor device 10 also has the semiconductor units 100 encapsulated in the second capsule 15.

With the semiconductor device 10, adhesion is improved by an anchoring effect produced by the channel portions 161 on the respective front surfaces of the plurality of semiconductor units 100 and engagement portions, out of the engagement portions 162, 163, 164, and 165, on sides where there is no engagement with another semiconductor unit 100. That is, the adhesion of the second capsule 15 to the semiconductor units 100 that are connected is improved. The plurality of semiconductor units 100 are connected by engagement of engagement portions, out of the engagement portions 162, 163, 164, and 165, that are decided by the layout of the semiconductor units 100. This means that the second capsule 15 does not become interposed between the semiconductor units 100 and it is possible to avoid separation of the second capsule 15 between the semiconductor units 100, which means that it is possible to prevent shifting of the semiconductor units 100. Accordingly, with the semiconductor device 10, it is possible to reliably encapsulate the plurality of semiconductor units 100 with the second capsule 15, to prevent breakages and the like due to mechanical damage to the semiconductor device 10, and to prevent a drop in the reliability of the semiconductor device 10.

### Second Embodiment

The first embodiment describes an example where the channel portions 161 formed on the front surfaces of the semiconductor units 100 are all oriented in a first (single) direction.

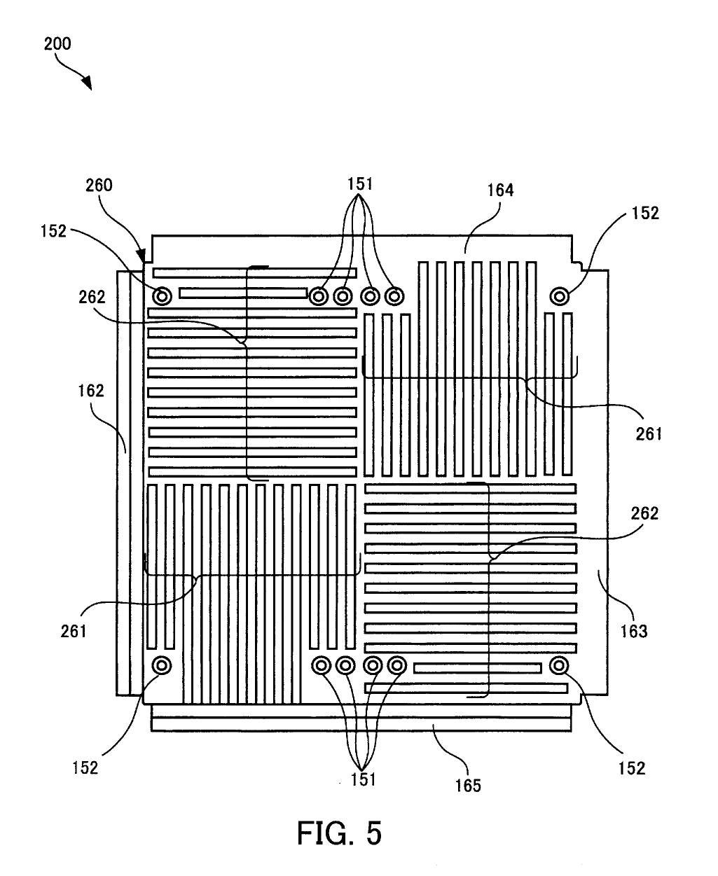

On the other hand, in the second embodiment, an example is described where the channel portions formed in the front surfaces of the semiconductor units included in the semiconductor device 10 are not all oriented in a single direction. This example is described below with reference to FIG. 5.

FIG. 5 is a plan view of a semiconductor unit according to the second embodiment.

Aside from the configuration of the channel portions formed in the front surface of a first capsule 260, each semiconductor unit 200 has the same configuration as the semiconductor units 100.

In each semiconductor unit 200, the front surface of the first capsule 260 is divided into four, i.e., two rows by two columns. Channel portions 261 in the up-down direction in FIG. 5 are formed in the upper-right and lower-left regions in FIG. 5. On the other hand, channel portions 262 in the left-right direction in FIG. 5 are formed in the upper-left and lower-right regions in FIG. 5.

With the semiconductor units 200, inside the semiconductor device 10, in the same way as in the first embodiment, the channel portions 261 and 262 formed in the respective front surfaces have an anchoring effect that increases adhesion on the first capsule 260. That is, the adhesion of the second capsule 15 to the semiconductor units 200 that are connected is improved.

Note that although an example where the front surface of the first capsule 260 of a semiconductor unit 200 is divided into four is described above, it is also possible to divide the front surface into two or more parts. The channel portions 261 and 262 are not limited to the example depicted in FIG. 5, and it is possible to provide the channels in freely chosen regions. The channel portions 261 and 262 are not limited to the up-down direction and left-right direction in FIG. 5, and it is possible to form channel portions in a diagonal direction, a wave-like shape, a wedge shape, a dot pattern, or the like, or any combination of these shapes.

### Third Embodiment

In the first embodiment, an example is described where the engagement portions 162, 163, 164, and 165 of the semiconductor units 100 are formed in key shapes.

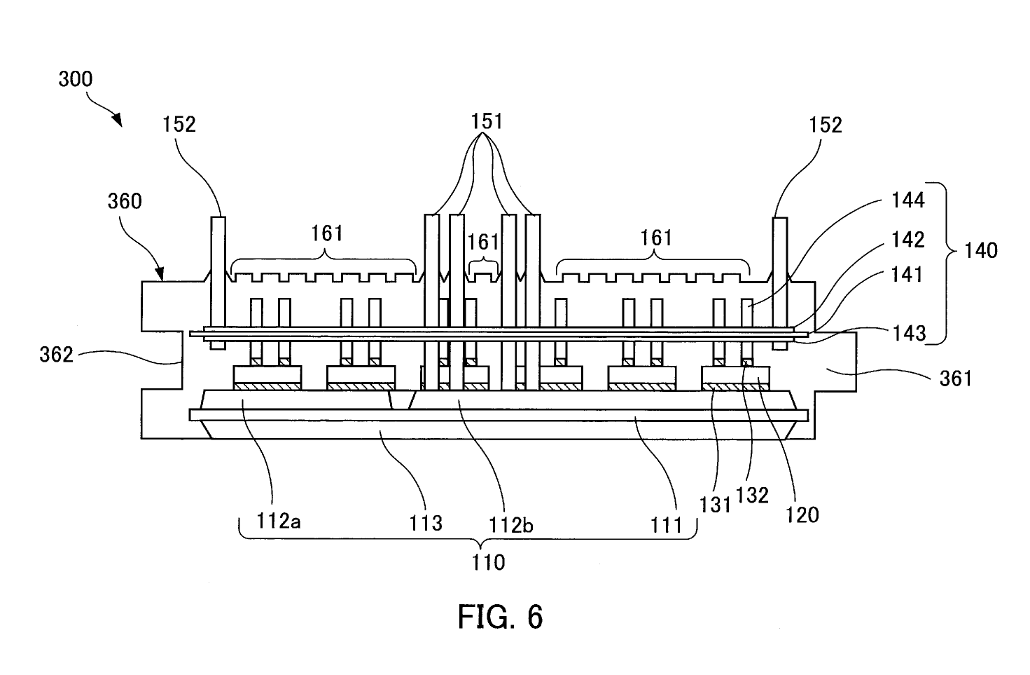

On the other hand, in the third embodiment, an example where the engagement portions of the semiconductor units have a different shape is described. This configuration is described with reference to FIG. 6.

FIG. 6 is a cross-sectional view of a semiconductor unit according to the third embodiment.

Aside from engagement portions 361 and 362 of a first capsule 360 and engagement portions at locations corresponding to the engagement portions 164 and 165 in FIG. 3, the configuration of each semiconductor unit 300 is the same as the configuration of the semiconductor units 100 according to the first embodiment.

The first capsule 360 of a semiconductor unit 300 has channel portions 161 formed in its front surface. Note that the channel portions 161 on the front surface of the first capsule 360 are merely one example and as another example, it is also possible to form the channel portions 261 and 262 described in the second embodiment.

A convex engagement portion 361 (on the right in FIG. 6) and a concave engagement portion 362 (on the left in FIG. 6) are formed on the first capsule 360. Note that the convex engagement portion 361 corresponds to the engagement portions 163 and 164 in FIG. 3 and the concave engagement portion 362 corresponds to the engagement portions 162 and 165.

The semiconductor units 300 are successively connected by fitting the engagement portion 361 of one semiconductor unit 300 in a pair of semiconductor units 300 into the engagement portion 362 of the other semiconductor unit 300 in the pair. The plurality of semiconductor units 300 connected in this way are provided via the solder 12a on the baseplate 11. The main terminals 151 and the control terminals 152 of each semiconductor unit 300 are connected to the printed circuit board 14a of the connection unit 14 and housed in the case 13. The inside of the case 13 is then filled with sealing resin to produce the second capsule 15 that encapsulates the baseplate 11, the plurality of semiconductor units 300 that have been connected, and the connection unit 14.

With this configuration also, for the plurality of semiconductor units 300 that are encapsulated in the second capsule 15, adhesion is improved by an anchoring effect produced by the channel portions 161 on the front surfaces of the semiconductor units 300 and the engagement portions 361, 362, and 163 on the sides where there is no engagement. That is, the adhesion of the second capsule 15 to the semiconductor units 300 is improved.

Also, since the semiconductor units 300 are connected by engagement of the engagement portions 361 and 362, the second capsule 15 does not become interposed between the semiconductor units 300, which means that it is possible to reduce separation and to prevent shifting of the semiconductor units 300.

Also, since the plurality of semiconductor units 300 according to the third embodiment are connected by engagement of the engagement portions 361 and 362, the second capsule 15 does not become interposed between the semiconductor units 300, which means that it is possible to reduce separation and to prevent shifting of the semiconductor units 300.

In addition, by forming engagement portions that engage the channel portions 161 on the semiconductor units 100 side of the printed circuit board 14a, it is possible to also prevent shifting of the printed circuit board 14a. Note that although a combination of the printed circuit board 14a and the channel portions 161 is used in the present embodiment, by forming engagement portions that engage the channel portions 161 on another member in which nut holes are formed, it is also possible to prevent components aside from the printed circuit board 14a from shifting.

Accordingly, in the semiconductor device 10 that is equipped with a plurality of the semiconductor units 300, the plurality of semiconductor units 300 are reliably encapsulated by the second capsule 15, so that breakage due to mechanical damage to the semiconductor device 10 is prevented and it is possible to avoid a drop in the reliability of the semiconductor device 10.

According to the present embodiments, it is possible to prevent mechanical damage to and breakage of a semiconductor device, which makes it possible to avoid a drop in the reliability of the semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a plurality of semiconductor units arranged in a matrix, each semiconductor unit
including a semiconductor element and a first capsule encapsulating the semiconductor element, and
having a plurality of convex portions formed on a front surface thereof, and an engagement portion through which said each semiconductor unit engages with at least one of the other semiconductor units; and
a second capsule encapsulating the plurality of semiconductor units.

2. The semiconductor device according to claim 1, wherein
each semiconductor unit further includes a connection terminal that is electrically connected to the semiconductor element and protrudes from the first capsule, and
the semiconductor device further comprises a connection unit that is electrically connected to the connection terminals of the semiconductor units, to thereby electrically connect the semiconductor units in parallel, at least a portion of the connection unit being encapsulated, together with the semiconductor units, in the second capsule.

3. The semiconductor device according to claim 2, wherein the connection unit has an engagement portion that engages with the plurality of convex portions of each semiconductor unit.

4. The semiconductor device according to claim 1, wherein
the engagement portion in each semiconductor unit is of a key-shape, and
the semiconductor units are connected by engagement of the key-shaped engagement portions.

5. The semiconductor device according to claim 1, wherein
the engagement portion in each semiconductor unit includes a convex portion and a concave portion, and
each adjacent two of the semiconductor units are connected by fitting the convex portion and the concave portion respectively of the engagement portions thereof together.

6. The semiconductor device according to claim 1, wherein the convex portions formed on the front surface of the first capsule include a plurality of channel portions.

7. The semiconductor device according to claim 6, wherein the plurality of channel portions include
a plurality of first channel portions formed in a first direction, and
a plurality of second channel portions formed in a second direction that is perpendicular to the first direction.
